(19) United States
(12) Patent Application Publication
(10) Pub. No.: US 2008/0289676 A1
(43) Pub. Date: Nov. 27, 2008

(54) ELECTRODE FOR A THERMAL BATTERY AND METHOD OF MAKING THE SAME

(76) Inventors: Ronald Armand GUIDOTTI, Colorado Springs, CO (US); Scott Brian Preston, Colorado Springs, CO (US)

Correspondence Address: KENYON & KENYON LLP, 1500 K STREET N.W., SUITE 700, WASHINGTON, DC, 20005, US

(21) Appl. No.: 11/754,000

(22) Filed: May 25, 2007

(51) Int. Cl. H01L 37/00; B05D 5/12

(52) U.S. Cl. 136/200; 427/58

(57) ABSTRACT

An aqueous slurry can be used to paint thermal electrodes onto a current-collector substrate with a spray gun for thin electrodes or pasting with a thickened slurry. A feedstock aqueous slurry can include thermal electrode components, thermal electrolyte components, a binder or thickening agent, and water. This slurry can be sprayed or pasted onto a substrate and dried. To obtain different densities, the substrate can be compressed to a desired density. Thermal electrodes of a desired size and shape can be cut or punched from the sheet. Different binders and/or binder concentrations can be used to adjust the viscosity and/or thickness of the electrode.

### BACKGROUND

Thermal batteries are used in a variety of applications. Typically, thermal batteries have a long shelf life and can be used under a wide temperature regime under severe environmental conditions, such as high shock, vibration, and spin.

A typical thermal battery uses a molten-salt electrolyte as the ionically conductive medium. At room temperature, the salt is solid, but upon application of an electrical or mechanical signal, the battery is activated and the internal pyrotechnic brings the battery up to its operational temperature. A typical operating temperature for a thermal battery may be as high as 400-550° C. Molten salts can have an ionic conductivity several orders of magnitude higher than materials used in conventional batteries, such as Li-ion batteries, allowing for very high power levels to be achieved.

A standard thermal battery consists of a stack of cells, each containing an anode, a separator, a cathode, and a pyrotechnic source. Typically, each layer or wafers is made by pelletizing powder mixtures. The cells are then stacked to obtain the desired discharge voltage under load. Thermal batteries are often hermetically sealed to provide long storage lifetimes as long as the hermeticity is maintained.

A thermal battery is essentially inert until the electrolyte becomes molten. Once activated, the battery can deliver power at rates often in excess of 1,500 mA/cm² for times on the order of seconds. At sufficiently low current densities (e.g., <50 mA/cm²), lifetimes can be extended to an hour or more. Each cell typically incorporates a pyrotechnic or “heat” pellet that is used to activate the battery. For example, a blend of a special iron and KClO₄ of varying proportions may be used, which are ignited by a Zr/BaCrO₄ fuse strip in contact with each pellet, or by an igniter such as an electroexplosive device.

Current thermal battery technology typically is based on a cathode of FeS₂ that contains an electrolyte and Li₂O as a lithiation agent to suppress a voltage spike that can occur at the start of discharge. The separator pellets use a special grade of MgO to hold the electrolyte in place by capillary action when molten. The anode pellet contains a blend of either Li(Si) or Li(Al) alloy and an electrolyte. The most popular anode is the 44% Li-56% Si (in weight percent) composition. A number of other electrolytes are available. For example, the LiCl—KCl eutectic that melts at 352 ° C. has been used. More recently, lower-melting electrolytes have used, such as the LiBr—KBr—LiF eutectic that melts at 317 ° C., and the LiBr—KBr—LiCl eutectic that melts at 321 ° C. Lower melting points generally provide a larger liquid region for battery operation, which can be useful for long-life (≧1 h) applications. In high-power applications, an all-Li LiCl—LiBr—LiF electrolyte has been used.

Presently, thermal batteries are manufactured exclusively by the pelletization of power blends. In these processes, all power and materials processing, pellet pressing, and battery assembly must take place in a dry-room environment where the moisture level is maintained at <3% relative humidity (RH). This can require a large amount of space for the large automated presses, blending equipment, and drying ovens and furnaces.

The steps involved in the preparation of separator pellets are illustrated in FIG. 1. Notably, the individual salts and the final separator mix must be vacuum dried before use. This is typically done overnight, reducing overall materials throughput. The LiCl and KCl must also be fused at high temperature for several hours to prepare the initial electrolyte mix. Thus, the cumulative time involved in just the preparation of the final separator mix is quite large. Although preparation of a catholyte is less time-consuming than preparation of the separator, the cathode pellets generally are still generally vacuum dried prior to assembly into the battery stack.

One challenge when using pellet technology is the need for increasing press sizes as the diameter of the pellet is increased, since the pressure required for pressing increases as the square of the diameter. For example, the use of 300-ton presses is not uncommon.

In addition, when the various powders are pressed into pellets, considerable stress remains in the pellets; this stress relaxes upon removal from the die. The pellet undergoes some growth during this relaxation, with the amount of growth being different depending on the specific materials used. Generally it is preferred that the separator pellet be slightly larger than the anode and cathode to prevent bridging by particles of active anode (such as Li(Si)) or cathode (such as FeS₂). As a result, different sizes of dies are needed for each battery design. An extensive die inventory can become quite expensive and can require a large amount of processing and/or storage space. In addition, maintenance costs and efforts can increase with an increasing number of dies. Each die must be cleaned and sharpened regularly to prevent binding during long pelletizing runs. Typically, thermal batteries are made in the shape of right circular cylinders. Special dies are necessary for odd shapes (such as “D” or half-moon).

Another issue with the use of discrete pellets involves the large number of parts that are needed per cell. For example, care must be taken during stack assembly not to put the cathode in upside down. The cathode is pressed onto a graphite-paper disc that serves as the current collector. If the cathode is placed in the battery stack upside down, this will effectively prevent the battery from functioning. Consequently, each constructed battery must be x-ray inspected to insure that the cathode is placed properly.

When a thermal battery is designed, the masses of anode and cathode that are necessary can be calculated and then translated into a pellet weight for a given diameter. Typically, there is much more active material present than is actually needed for a given application. This results from the need to make the pellets thicker strictly for mechanical reasons. For example, it is almost impossible to press a 3″-dia. pellet that is less than 0.020″ thick. In addition, if the pellets are too thin, they are subject to chipping and breakage while handling during battery-stack assembly. There is also the danger of soft, low-density spots when pressing thin separator pellets with diameters greater than 2″. This can give rise to formation of a hole in the separator upon melting of the electrolyte, leading to breach of a cell. Such a short will allow direct contact of the anode and cathode, resulting in very exothermic reactions taking place. Such reactions can lead to a thermal-runaway condition in which the battery destroys itself.

The use of plasma or thermal spraying for the fabrication of electrodes has been examined as an alternative to conventional pressing of powder mixes. Since FeS₂ thermally decomposes above 550 ° C., using such material as a feedstock alone would not be practical. However, by coating the pyrite with elemental sulfur, the thermal decomposition is repressed via LeChatlier's principle; i.e., the reaction is driven to the left:

FeS₂₍ₛ₎→FeS₍ₛ₎+0.5S_{2(g)}

However, the presence of elemental sulfur in the pyrite cathode of a thermal battery often gives rise to a voltage “spike” at the start of discharge, which is unacceptable, since such batteries typically have strict voltage regulation limits imposed on them. By mixing the same electrolyte that is used in the battery with the FeS₂ feedstock, it has been found that it coated the pyrite particles and acted as a thermal-barrier coating while passing through the plasma. It therefore is possible to deposit thin (100-300 μm) FeS₂ cathodes with this technique. This can allow for the construction of batteries with only the requisite amount of active cathode. The thinner cathode typically is lighter and consequently requires a smaller (lighter) heat pellet, resulting in a battery that is lighter and smaller. This translates into increased specific energy (Wh/kg) and energy density (Wh/L).

Initial plasma spraying work used a LiCl—KCl eutectic electrolyte, but it was shown that other electrolytes, such as the all-Li LiCl—LiBr—LiF electrolyte, also could be used. Some work was done plasma spraying the separator onto the plasma-sprayed cathode to make a two-layered cathode-separator composite. Later, it was shown that CoS₂ could also be plasma sprayed.

Electrodes constructed using plasma spraying may have some advantages over pressed pellet electrodes. For example, varying sizes of cathode electrodes can be readily punched from the graphite-paper sheets coated with pyrite using inexpensive “cookie cutter” dies. A 3″ diameter cathode can often be as easily punched as a 1″ diameter cathode, without the use of expensive presses and dies. Similarly, odd-shaped cathodes can be cut. Thinner electrodes having only the required amount of electroactive materials may be possible, reducing the size and weight of the battery. Improved electrochemical performance is obtained due to better particle-particle contact within the electrode. Thinner electrodes also have lower ohmic losses. The process can also be robotically controlled to provide better uniformity of deposit. In principle, plasma spraying also allows for fabrication of multiple-layered electrodes, thus saving battery-assembly time.

However, plasma spraying is not an optimal electrode construction technique for several reasons. For one, it requires the use of expensive equipment. Typical plasma-spraying equipment is quite expensive and requires significant space and considerable skill in operation. The flow characteristics of the feedstock must be strictly controlled to achieve uniformity of deposit thickness. Some materials do not flow very well, resulting in a variable, nonuniform rate of deposition.

Plasma spraying also must be done under argon in an enclosed chamber to protect the sample from air oxidation. After spraying, the samples must be protected from the ambient environment prior to being processed into electrodes. The amount of argon that is consumed in the process is also quite high.

Another drawback of plasma spraying is that the composition of the deposit is not the same as that of the feedstock, with the electrolyte concentration in the deposit being much higher. For example, an electrolyte content of 44.5% in the final deposit resulted from using a feedstock electrolyte content of only 20%. This lack of control of composition would not be acceptable for commercial production of thermal batteries.

Furthermore, the deposit density is low and can't be readily controlled. Traditional pressed pellets are made to a density of 73%-75% of theoretical density (TD). For plasma-sprayed cathodes, densities of 50% TD or less are typical. Control of density is especially important when fabricating the separator component. Low separator densities can result in collapse of the electrode structure during discharge, reducing the interfacial contact between electrodes and causing an increase in impedance. Densities over 50% TD have not been achieved for either the FeS₂- or CoS₂-based plasma-sprayed cathode deposits regardless of the electrolyte used.

Plasma spraying is also intrinsically a batch process, which greatly reduces the throughput that is possible.

Attempts have also been made to fabricate thermal electrodes using tapecasting and similar techniques using volatile binders which are removed by a heat treatment before battery assembly. These approaches have several disadvantages. There is little control over electrode density, which is an important parameter in thermal battery fabrication. It is also difficult to maintain dimensional control of the electrode after the heat treatment, which can affect initiation of the resulting battery. For proper initiation to occur, the pyrotechnic heat pellet must extend away from the cell to make sufficient contact with the fuse train, and the separator typically should not be smaller than the other electrodes to prevent shorting during operation.

### SUMMARY OF THE INVENTION

An aqueous slurry can be used to paint a thermal electrode onto a current-collector substrate by spraying or pasting. A feedstock aqueous slurry can include thermal electrode components, thermal electrolyte components, a binder or thickening agent, and water. This slurry can be sprayed or pasted onto a substrate and dried. To obtain different densities, the substrate can be compressed to a desired density. Thermal electrodes of a desired size and shape can be cut or punched from the sheet. Different binders and/or binder concentrations can be used to adjust the viscosity and/or thickness of the electrode.

### BRIEF DESCRIPTION OF THE DRAWINGS

FIG. 1 shows the steps involved in a conventional process for preparing separator pellets for use in fabricating a thermal battery using a pressed-powder technique.

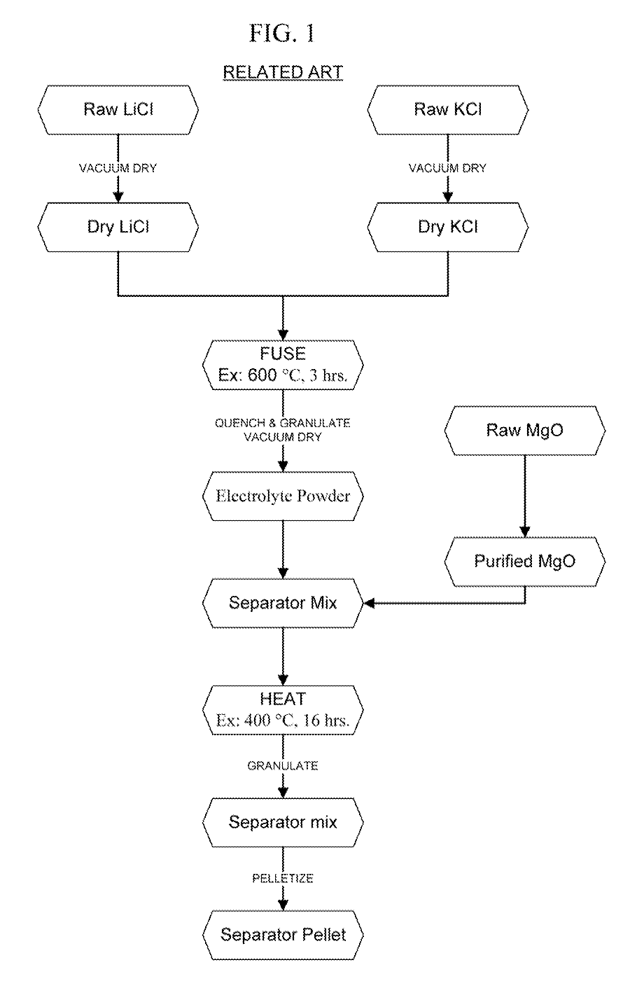

FIG. 2A shows an exemplary process for fabricating a thermal electrode by spraying or pasting.

FIG. 2B shows an exemplary process for fabricating a thermal electrode by spraying or pasting.

FIG. 3 shows a process for fabricating an exemplary cathode using spraying or pasting.

FIG. 4 shows an exemplary thermal cell stack according to the present invention.

FIG. 5 shows an exemplary process for fabricating a thermal cell.

FIG. 6 shows an exemplary process for fabricating a thermal cell.

FIG. 7 shows an exemplary process for fabricating a thermal cell.

FIG. 8 shows an exemplary process for fabricating a thermal cell.

FIG. 9 shows discharge behavior at 400° C. for a single cell made with a painted cathode.

FIG. 10 shows discharge behavior at 450° C. for a single cell made with a painted cathode.

FIG. 11 shows discharge behavior at 500° C. for a single cell made with a painted cathode.

FIG. 12 shows discharge behavior at 550° C. for a single cell made with a painted cathode.

FIG. 13 shows the voltage temperature dependence of the cells described with respect to FIGS. 9-12.

FIG. 14 shows the total cell polarization for the cells described with respect to FIGS. 9-12.

FIG. 15 shows cell voltage and total cell polarization for a pressed-powder cell.

FIG. 16 shows discharge rates for cells having a pressed-powder cathode, a plasma sprayed cathode, and a painted cathode.

### DETAILED DESCRIPTION

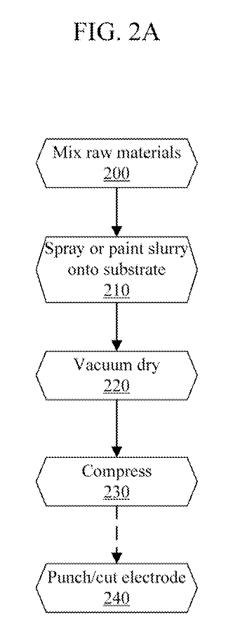

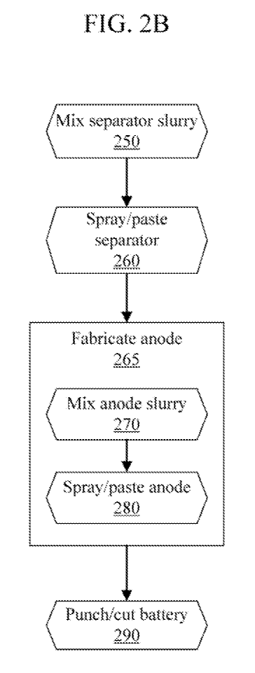

An aqueous slurry can be used to fabricate thermal electrodes (i.e., electrodes suited for use in a thermal battery) on a current collector substrate by painting (spraying) or pasting. As used herein, “pasting” includes the process of doctor-blading. As used herein, “spraying” refers to painting a layer using a spray gun or other controllable nozzle, but does not include processes such as plasma spraying. For electrodes about 0.005 inches thick or less, spraying may be preferred, whereas pasting may be preferred to achieve thicker electrodes. Generally, the fabrication of the slurry and subsequent electrode fabrication steps are the same for spraying and pasting. FIG. 2A shows an exemplary process for fabricating a thermal battery electrode by spraying or pasting. An aqueous slurry can be formed by mixing a thermal electrode material, a thermal electrolyte material, and water 200. As used herein, a “thermal” electrode, electrolyte, or other material or component is one that is suitable for use in a thermal battery. The systems and methods described herein can be used to create components for use in a thermal battery, though such components may be referred to simply as an electrode, electrolyte, etc. A binder or thickening agent may be used to prevent the slurry from separating. In general it is preferred that the slurry be homogeneous, i.e., for each material in the slurry to be evenly distributed throughout the slurry.

The slurry can be sprayed onto a substrate 210, such as graphite paper. A uniform coating of slurry is preferred. As further described below, the spray speed and/or the separation between the spray nozzle and the substrate separation can be adjusted to achieve a uniform coating. The coated substrate is then dried 220, generally using a vacuum drying process. If a thermal electrode having a higher density and/or lower thickness is desired, the dried substrate sheet can be compressed, such as by rolling through a calender 230. Electrodes are then punched or cut from the sheet in a desired shape and size 240. Notably, arbitrary shapes and sizes may be created without requiring changes to the electrode fabrication process. Typically, the process illustrated in FIG. 2A may be used to fabricate a cathode using a current collector substrate such as a graphite sheet. In many common battery chemistries, lithium-based anode materials are used, with which an aqueous slurry would react violently. Thus, a solvent other than water, such as an organic solvent, may be used to form the anode slurry. Organic binders that evaporate at a temperature lower than the melting point of the lowest-melting point electrolyte may be used to allow for binder removal by heating. Similarly, an organic binder can be used to bind alloy particles to a stainless steel current collector. As a specific example, poly(isobutylene) (PIB) may be used. A coated anode may also be heated to a temperature just above (i.e., about 5-20 ° C.) the melting point of the electrode for a short time, typically around 5-10 minutes.

It may be preferred for an aqueous solution used to deposit an electrode to be saturated with the same electrolyte used in the cathode and/or separator of the final thermal cell. This can prevent the slurried powders from dissolving in the solution. If the aqueous medium is saturated with the electrolyte, the final compositions of the deposited layers (typically the cathode and/or separator) will not change throughout the spraying/pasting process. Thus, the composition of the resulting layers can be more precisely controlled than in conventional fabrication techniques.

A complete thermal battery cell also may be fabricated using methods similar to those described with reference to FIG. 2A. For example, referring to FIG. 2B, after fabricating a cathode using the process in FIG. 2A, a separator slurry 250 and/or an anode slurry 270 can be prepared. The separator can be painted on the cathode 260 by spraying. An anode can then be fabricated 265 and combined with the cathode/separator structure, and a complete cell cut from the resulting layered structure 290. Fabrication of the anode may be performed separately, such as by preparing an anode slurry 270 and depositing the slurry on a current collector. The anode also may be painted onto the separator by spraying. For example, an anode slurry using lithium-based materials may be sprayed on a stainless steel current collector. Typically any additional layers may be added after each of the previous layers is vacuum dried. The cell may be compressed after each layer is deposited, and/or after all the layers have been deposited. It will be understood that various other layers may be deposited depending on the specific structure desired. The steps shown in FIG. 2B may also be performed at various times relative to the steps shown in FIG. 2A. For example, where a cathode is fabricated according to the process of FIG. 2A, a separator slurry and anode slurry may be prepared separately from the cathode slurry. After a complete cathode is fabricated such as by the process of FIG. 2A, the completed cathode may be used as a substrate for the part of the process of FIG. 2B, allowing for fabrication of a complete cell. In this case, it may not be necessary to punch or cut the final cell 290, since the cell shape can be determined during production of the cathode as described with reference to FIG. 2A and the separate production of the anode. The cell also may be fabricated prior to punching to a desired shape. As described in further detail below, various portions of the complete cell may be fabricated in separate processes performed serially or in parallel, allowing for flexibility in cell fabrication.

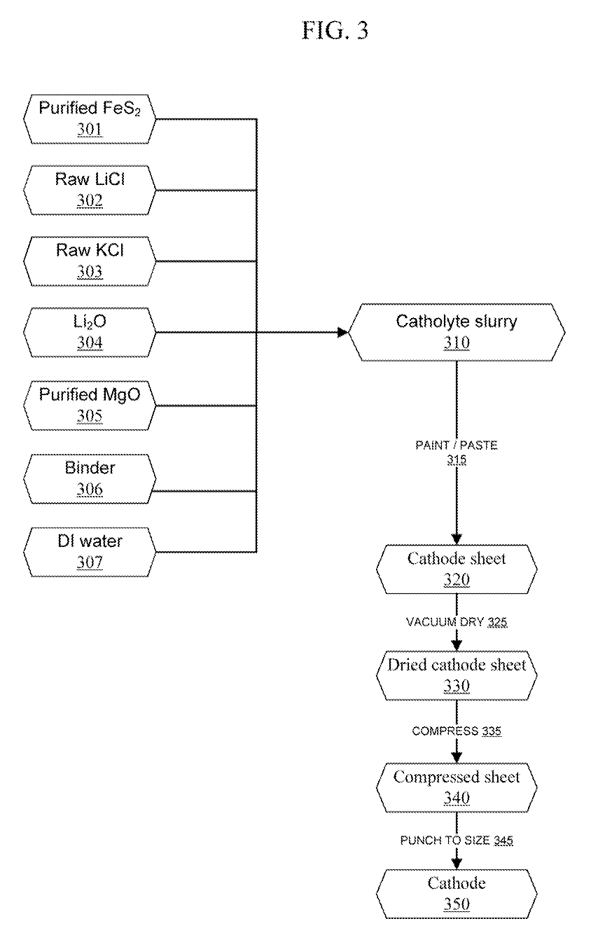

A process for fabricating an exemplary thermal cathode is shown in FIG. 3. All materials processing can be performed under ambient conditions in a “wet” lab. This is advantageous, since conventional thermal battery fabrication techniques must use a dry room for cell assembly. As used herein, a “wet” lab or room refers to an environment in which the relative humidity is not strictly controlled or limited, in contrast to a dry room that typically is maintained at 3% or less relative humidity. A dry room generally requires a much higher degree of maintenance than is required for a wet lab, so use of a wet lab can decrease fabrication and assembly time, complexity and cost.

Still referring to FIG. 3, a feedstock aqueous slurry can be made by blending together the salt components 302, 303 (without vacuum drying), MgO 305, and FeS₂ 301 with an oxide binder or thickening agent 306 and water 307 to form a slurry 310. The slurry is then sprayed 315 onto a graphite-paper substrate to form a cathode sheet 320, which is then vacuum dried 325. If a thinner or higher-density cathode is desired, the sheet can be compressed 335 to the desired density and/or thickness 340. A thermal cathode of the desired size and shape 350 can then be punched 345 from the cathode sheet. The final step of punching/cutting the electrode may be performed in a dry room at less than 3% relative humidity. The relative amount of solid material in the aqueous slurry can be adjusted to be lower when depositing via spraying, or higher for pasting electrodes.

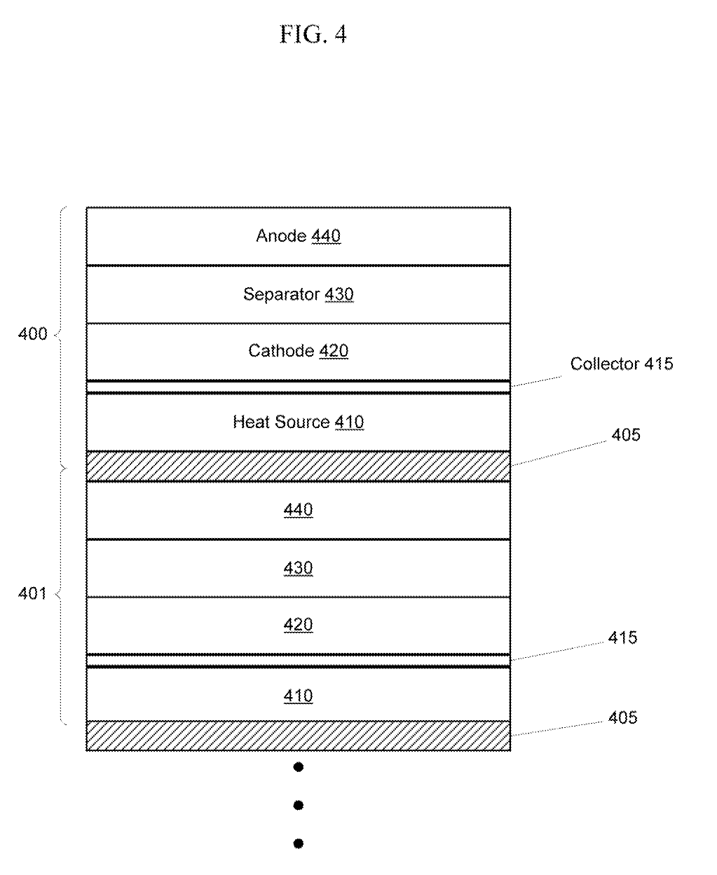

An exemplary thermal battery according to the present invention is shown in FIG. 4. Each cell 400, 401 in the battery can include a heat source 410, current collector 415, cathode 420, separator 430, anode 440 and current collector 405. The current collector 415 may be, for example, a graphite sheet such as GRAFOIL® flexible graphite; the current collector 405 may be stainless steel or a similar metal. Typically, the separator 430 is painted onto an anode 440 or a cathode 420. In contrast to conventional thermal cells, the cathode, anode, and/or separator according to the invention may have better particle-to-particle contact, providing improved performance and other advantages described herein. Exemplary materials for use in the anode include Li, Li(Si), and Li(Al). Exemplary materials for use in the separator include combinations of MgO and an electrolyte such as LiCl—KCl, LiCl—LiBr—LiF, LiBr—KBr—LiF, and LiBr—KBr—LiCl. Exemplary materials for use in the cathode include FeS₂ and CoS₂, which may be blended with a separator material. The heat source may be a typical heat source used with conventional thermal batteries, such as Fe/KClO₄ mixtures.

Control over the thickness (mass) of the layers in a thermal cell is important, as the overall cell mass directly affects the mass of pyrotechnic needed for a given battery design. The mass of the heat source per cell is determined by calculating the desired heat output per total mass of the thermal cell, including the mass of the heat source. Depending on the thermal properties of the components (e.g., heats of fusion of the electrolyte, Cₚ values), the range of activation temperatures, thickness of the current collector, the load profile, and the amount of thermal insulation, the heat balance is typically in the range 85 cal/g-120 cal/g. Higher values are typically associated with short-lived (less than 10 s) pulse batteries.

The mass of the pyrotechnic generally determines the final operating temperature of the battery stack, so control over the pyrotechnic mass is important to maintain a high reliability in performance from battery to battery and from lot to lot during mass fabrication. A large variability in the combined masses of the components in a composite multilayered cell can affect the final heat balance in the battery, which, in turn, will impact performance. The spray fabrication methods described herein may allow for greater control over the mass of the various layers in a cell, allowing for uniform, large-scale fabrication of thermal cells and batteries. Statistical process control and/or robotic fabrication methods may also be used with the fabrication techniques described herein to further control component uniformity.

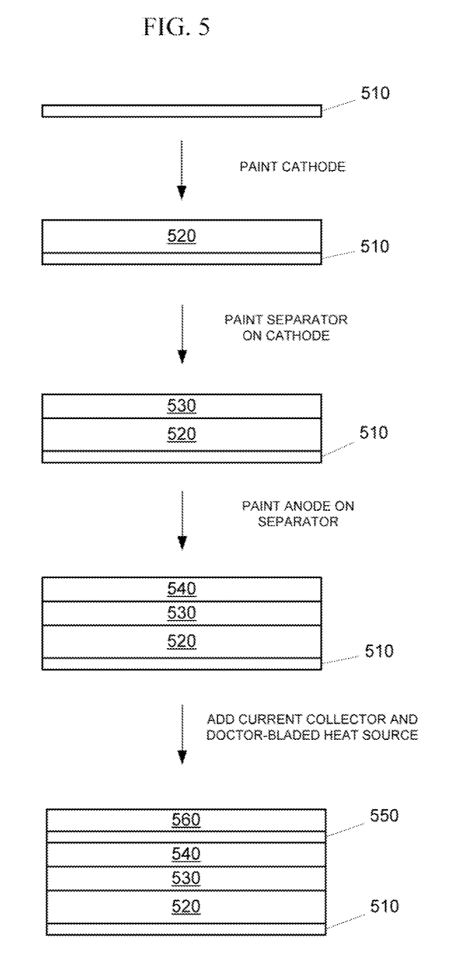

FIG. 5 shows an exemplary method of fabricating a complete cell starting with deposition of the cathode 520 onto a current collector 510, such as a graphite paper substrate. In this approach, a three-layered cell including a cathode 520, separator 530 and anode 540 is mated with a heat source 560 deposited onto a current collector to form the final thermal cell. This two-part fabrication can allow for greater control over the mass of the heat sources, electrode layers and separator layer in the cell than typically is possible using conventional pressed-powder techniques.

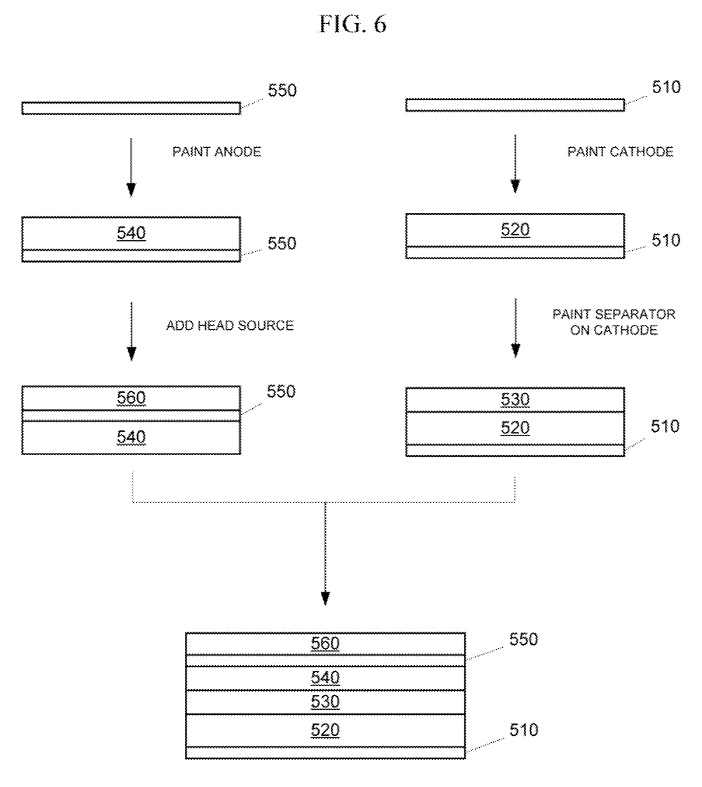

FIG. 6 shows an exemplary method of fabricating a complete cell in which only two layers are deposited in the first step to form a composite having a cathode 520, separator 530 and a current collector 510. In a separate process, an anode 540 may be deposited onto one side of a current collector 550. A heat source 560 is then deposited on the other side to form an anode-heat composite. This composite is then combined with the cathode-separator composite to form a complete cell.

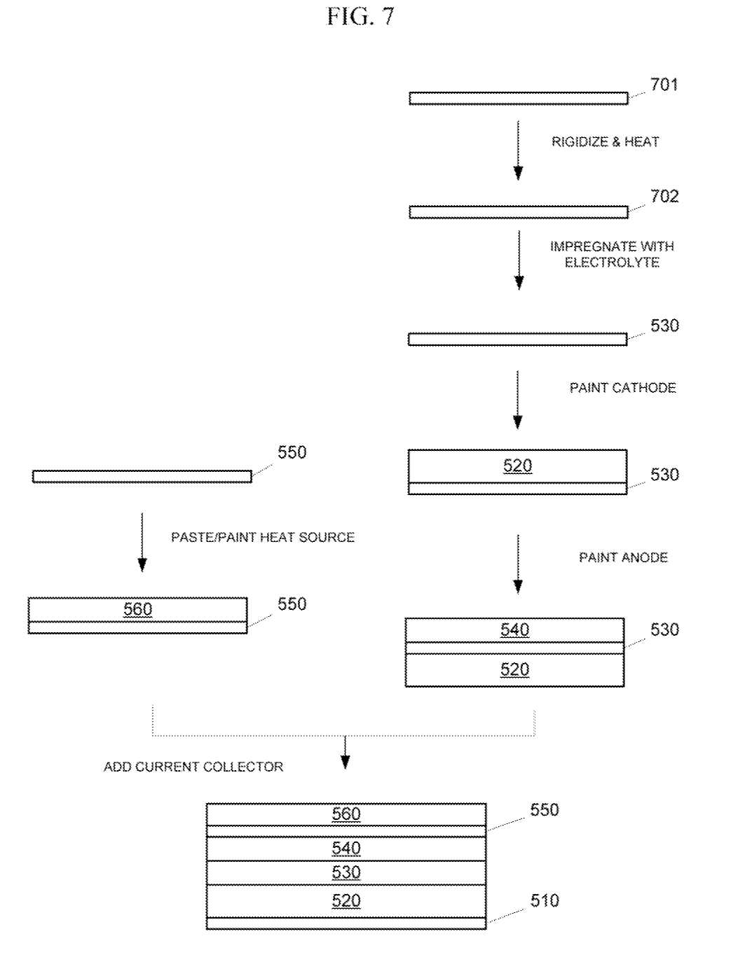

FIG. 7 shows an exemplary method of fabricating a thermal cell in which a rigid separator 701 is prepared. A separator material is treated with a rigidizing solution and heat to form a rigid separator, which is then impregnated with electrolyte. Exemplary materials for the separator include ZrO₂, Al₂O₃, Aluminosilicate, and ceramic felts. A cathode 520 may be painted on the separator layer 530 to form a cathode-separator composite. The anode layer 540 may be painted or pasted onto this composite to form a three-layered cell. A heat source 560 may be deposited separately onto a current collector 550 and the resulting structure combined with the three-layered cell and a second current collector 510 to form the thermal cell.

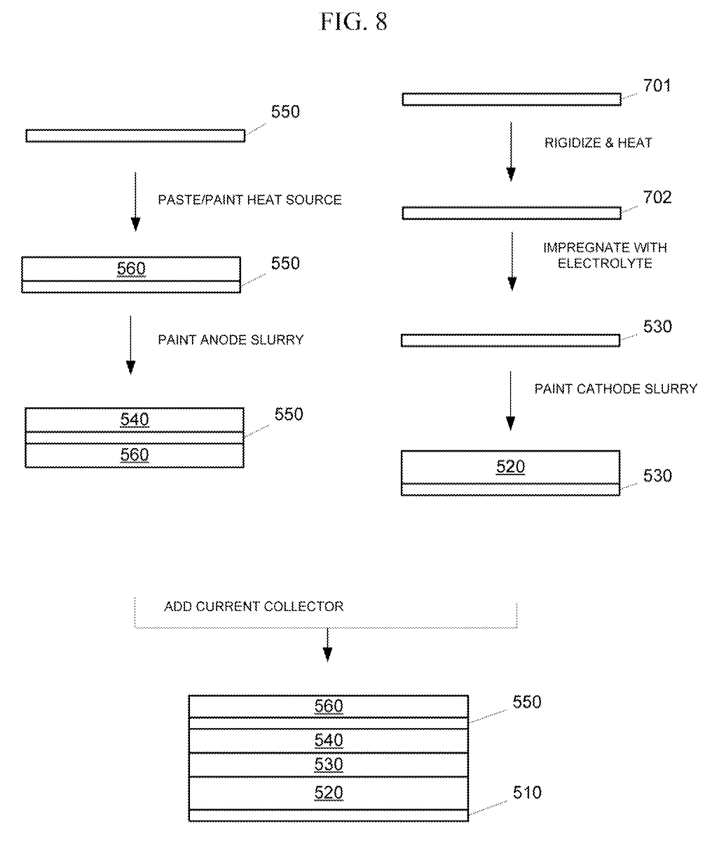

A similar process is shown in FIG. 8, in which a cathode-separator composite is formed in a first process and an anode-heat composite is formed in a second process. The two composites are then combined with a current collector to form the final thermal cell.

The spraying/pasting processes described herein may be more flexible and more easily performed than other methods, since there is no need for the entire process to be performed in a dry-room space. All materials processing and spraying can be performed under ambient conditions. Painted samples may be moved to a dry room for assembly after they have undergone a single vacuum-drying operation, thus reducing the overall time needed for electrode fabrication.

The equipment needed for electrode spraying or pasting is less complex and less expensive than equipment used for other methods. For example, an off-the-shelf, commercially-available paint gun can be used for applying the thin electrode films. Similarly, the cutting dies used for punching electrodes are inexpensive and require less maintenance than conventional pelletizing dies. In contrast, conventional cathode preparation often uses large, expensive presses. Since the force required for pressing increases as the square of the diameter, larger and larger presses are needed for larger-diameter pellets. Different sized dies are needed for the various cell components (heat, anode, separator, cathode) using conventional pressing dies.

In contrast to conventional fabrication techniques, fabricating thermal electrodes by spraying does not require a large pressing-die inventory. Instead, simple cutting dies can be used to punch battery components from painted sheets of graphite paper, such as GRAFOIL®. These dies typically are easier to maintain than conventional pelletizing dies.

The spraying/pasting process can also allow for fabrication of a range of sizes and shapes not typically attainable using pressed-powder dies and methods. For example, prismatic and odd-shaped conformal batteries may be fabricated. Notably, a prismatic design can provide efficient use of insulation and does not require the skilled machining of sleeves made from thick expensive blocks of material. Conformal batteries also may be achieved due to efficient adhesion of the deposited slurry to the substrate, allowing for flexible electrodes. Electrode density also may be controlled by the use of subsequent surface-pressing of the painted substrate.

Spraying/pasting requires much less use of a dry-room, decreasing the environmental impact, complexity, fabrication time, and labor required when compared to conventional fabrication techniques.

Fabrication of multilayered composite electrodes may be accomplished using the methods described herein. For example, a separator can be sprayed or doctor bladed onto a previously-painted or -pasted cathode to form a cathode-separator composite. Similarly, an anode can then be deposited on the separator to form a complete cell. Thus fewer parts are needed for battery assembly, reducing the chances of error and associated labor. Further, the use of spraying techniques allows for better control over electrode density and electrode component dimensions. Since the deposited electrode material is the same as the mixed slurry, the electrode density can be controlled directly. The dimensions and relative sizes of the cell components can also be controlled, since the cells can be punched or cut to a desired shape and/or size during or after fabrication.

The spraying/pasting process generally is not affected by electrolyte or cathode composition. This allows the use of various electrolytes depending on the particular application. For example, LiCl—KCl, LiBr—KBr—LiCl, and CsBr—LiBr—KBr eutectic electrolytes can be used to fabricate FeS₂ thermal cathodes. The spraying/pasting process therefore can be extended as new chemistries and/or materials are developed. In addition, the composition of the deposited material is the same as that of the slurry feedstock, in contrast to methods such as plasma spraying. The spraying/pasting methods described herein therefore may allow for better control of the composition of fabricated electrodes.

The spraying process may be used in semi-continuous or continuous processing. For example, a feed reel of a substrate such as graphite paper could be painted with a cathode and then passed through a moving-belt furnace to remove water before being feed to a take-up reel for subsequent processing in the dry room.

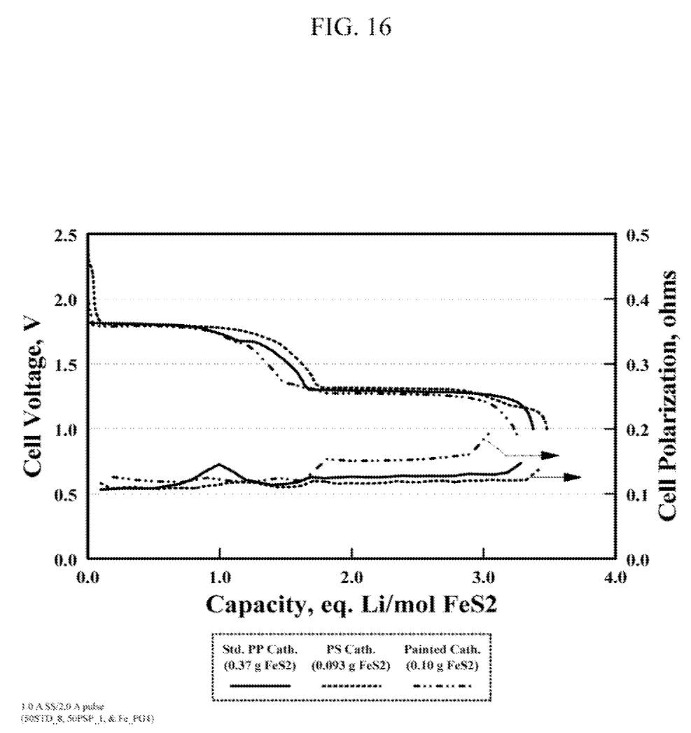

Electrodes fabricated by spraying or pasting can perform as well as or better than cells made with conventional pressed-powder electrodes. An example is shown in FIG. 16 for a Li(Si)/LiCl—KCl (MgO)/FeS₂ cell made with a painted cathode. Comparable data for a cell with a plasma-sprayed cathode and a pressed-powder cathode are shown for comparison.

The methods described herein also allow for additional fabrication techniques. For example, a thermal cathode can be painted onto a porous ceramic-disc separator that has been impregnated with electrolyte to form a separator-cathode composite. A thermal anode can then be painted on the separator to make a complete cell. It has been found that such separators may have superior performance compared to conventional pressed-powder separators. In addition, this process can provide a mechanical separator between the anode and cathode, thus reducing the chance for breaching that can occur under certain conditions with pressed-powder separators.

Experimental

An aqueous slurry of catholyte material and a CAB-O-SIL® fumed silica suspending agent was prepared at various weight percentages. The viscosity was measured using a #3 spindle at 12 rpm and 21° C.

| | Initial | Viscosity | Viscosity |
|---|---|---|---|
| Weight-% Fumed | Viscosity | after 1 min. | after |
| Silica | (cP) | (cP) | 30 min. (cP) |
| 0 | 3000 | 2700 | 2000 |
| 0.25 | 4000 | 3300 | 3200 |
| 0.5 | 4200 | 3800 | 3400 |
| 0.5 (measured in | 4100 | 3600 | 3400 |
| upper third of | | | |
| sample) | | | |
| 0.75 (measured in | 5600 | 5500 | 5100 |
| upper third of | | | |
| sample) | | | |
| 1.00 | 6500-8000 | 6500-8000 | 6500-8000 |

At 1.00% fumed silica, the slurry essentially became a paste. It was found that 0.25 wt-% was suitable for use in spraying without overly thickening the slurry, and this level was used in subsequent spray trials.

An aqueous slurry containing 73.5 g FeS₂, 8.1 g MgO, 1.5 g Li₂O, 0.375 g CAB-O-SIL®, and 67.2 g LiCl/KCl/water (90 g LiCl, 110 g KCl, 597 g water) was prepared. The dry powders were thoroughly mixed before addition of the aqueous phase to prevent coagulation of the MgO. A 45 μm powder of FeS₂ was washed with 1:1 HCl and water, then dried and passed through a 300 μm sieve. Powders of MgO (45 μ) and LiO₂ (250 μm) were used. The resulting slurry was not observed to clog or jam the spray nozzle, and the same formulation was used in subsequent spraying studies. A commercially-available paint sprayer was used to spray the slurry. It was found that a vertical, high-volume staining nozzle was suitable for spraying.

Various spray distances and spray rates were tested. At less than about 8 inches, the sprayed surface was uneven and exhibited runs in the deposited material. At distances of about 8-10 inches a uniform coating was obtained. At distances over 12 inches, individual droplets of slurry were deposited on the substrate. It was found that higher spray rates with low passes resulted in more uniform coatings. Uniform coatings were achieved even with application of up to 10 coats.

For pasting, a more viscous film was used. Studies were conducted using a slurry of 24.5 g FeS₂, 5.6 g LiCl/KCl (45/55%), 2.7 g MgO, 0.125 g CAB-O-SIL®, and 8.27 g water. As with the slurry used for spraying studies, the solids were mixed prior to addition of the water to achieve a homogeneous slurry. The slurry was applied to the substrate using a doctor blade, then vacuum dried. A uniform coating was achieved.

For both the sprayed and pasted electrodes, the deposited material was observed to have good adhesion to a GRAFOIL® substrate. The sprayed electrode was also observed to exhibit flexibility. Electrodes were punched from the coated substrate with no cracking or peeling. The punched edge was observed under a magnifying glass and appeared as a clean cut.

The sprayed and pasted electrodes were found to be about 30-50% of the theoretical density of their constituent parts. To increase the density, a calender can be used to increase the density. A sprayed electrode sheet was successfully calendered to a density of 2.92 g/cc (76% of the theoretical density), with the thickness decreasing from 0.0075 inches to 0.0035 inches. A painted sheet was calendered to a density of 2.68 g/cc (70%), with a thickness change from 0.0130 inches to 0.0084 inches. The calendering process may also increase the adhesion of the electrode material to the substrate.

A test cell was prepared for a sprayed electrode and a painted electrode. Each cell contained a painted or pasted cathode, a pressed-powder separator and anode, and nickel current collectors. The cell was placed between mica sheets for testing. The testing apparatus used two heated platens and a stage to hold the test cell, which was moved between the platens and the upper platen lowered onto the cell. Tests were conducted under a dry argon atmosphere in a glove box. The cathodes were fused at 400° C. for 15 minutes. In contrast, a similar pressed-powder process would require fusing for about 8 hours. Data were generated as a function of temperature for Li(Si) (flooded, 15% E)/LiCl—KCl (MgO)/FeS₂ (lithiated) single cells. Tests were performed on a 1 inch diameter cell at a current density of about 125 mAWcm². Preliminary data were also generated at 500° C. using a pressed-powder cathode and similar anode and separator as used for the painted cathode cells.

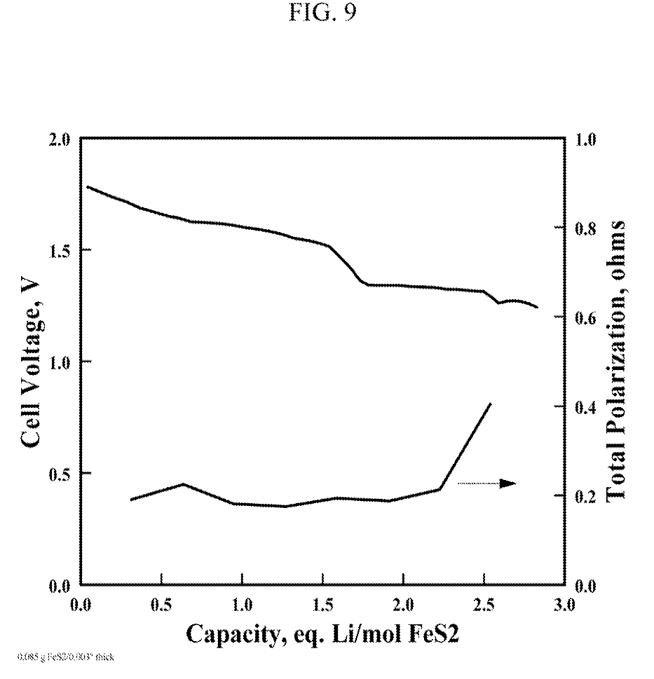

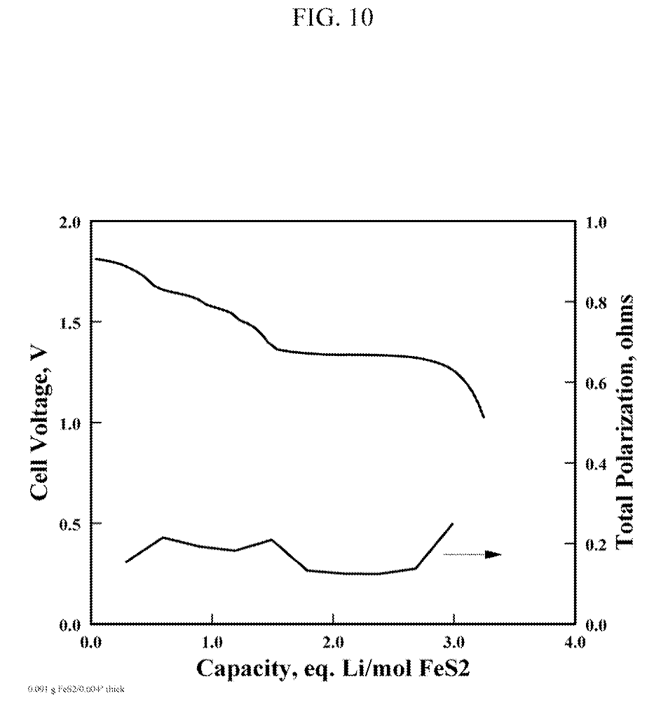

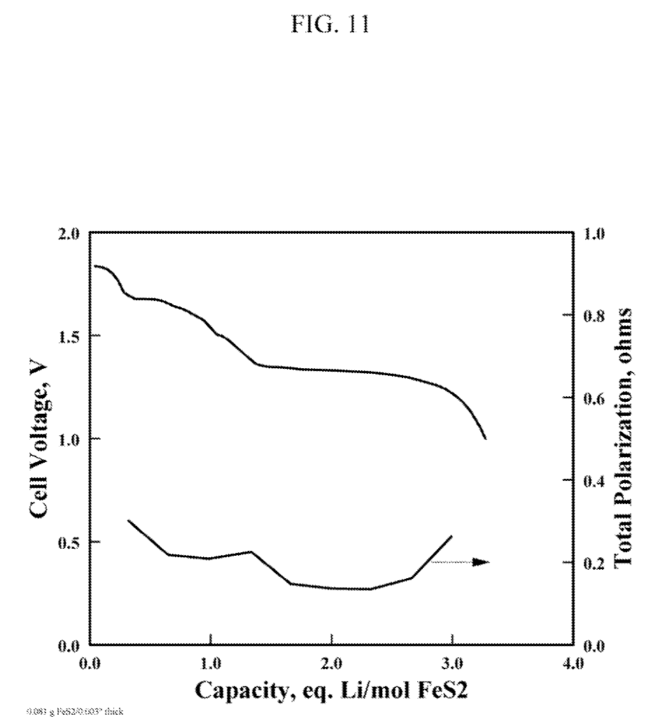

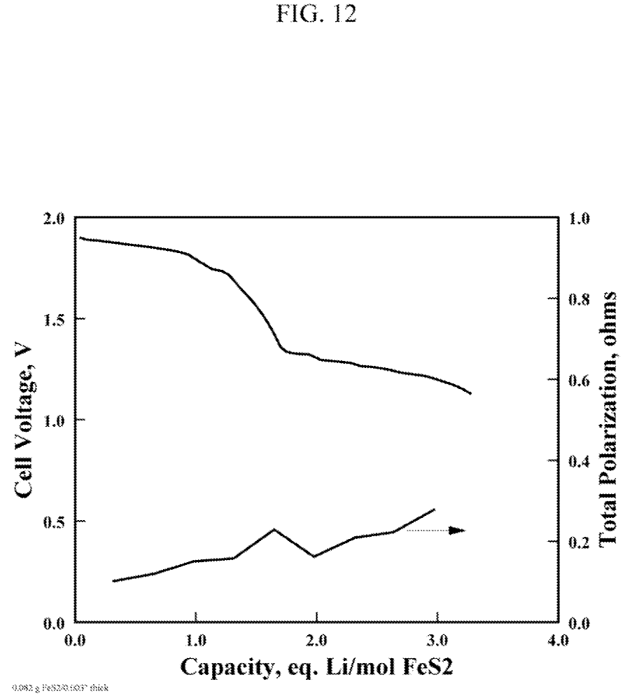

The data generated in these tests appears to be representative of expected voltage and polarization behavior. FIGS. 9-12 show discharge behavior at 125 mAcm₂ at 400, 450, 500 and 550° C., respectively, for a 1 inch diameter Li(Si) (15% E)/LiCl—KCl (MgO)/FeS₂ single cell made with a painted electrode. The FeS₂ electrodes for each trial had the following dimensions:

| Discharge | Electrode | Electrode |
|---|---|---|
| Temp. (° C.) | Weight (g) | Thickness (in.) |
| 400 | 0.085 | 0.003 |
| 450 | 0.091 | 0.004 |
| 500 | 0.081 | 0.003 |
| 550 | 0.082 | 0.003 |

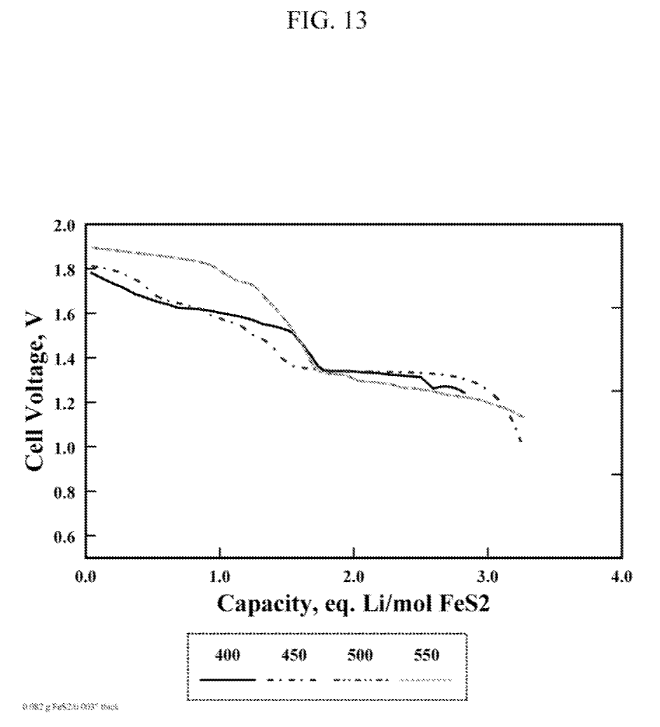

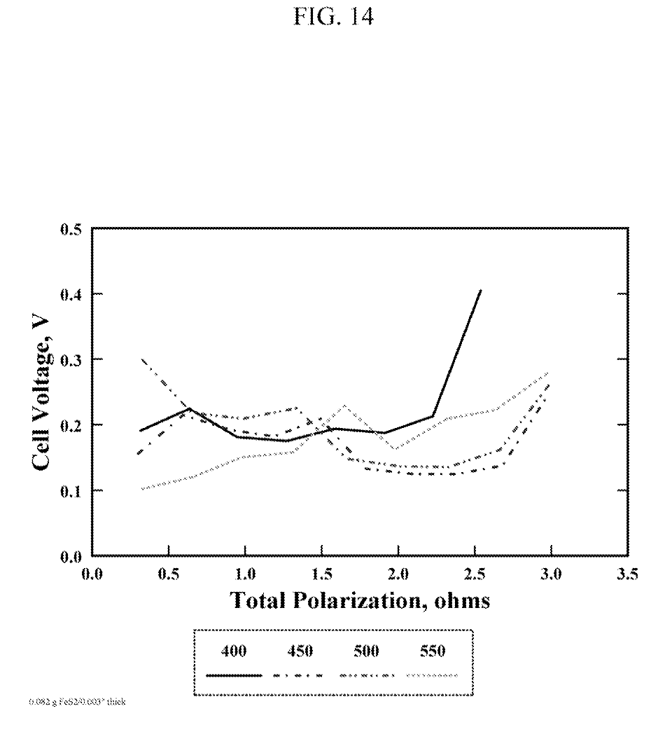

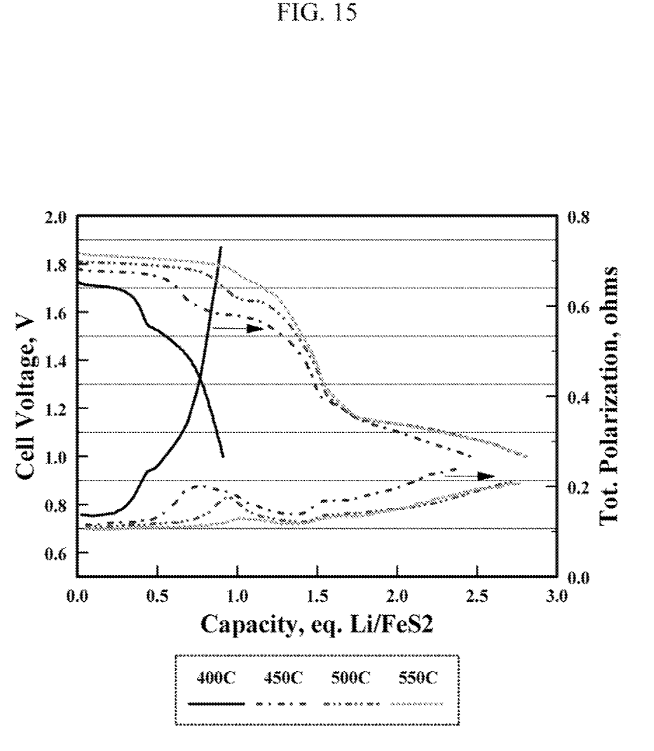

FIG. 13 shows the voltage temperature dependence of the cells described with respect to FIGS. 9-12. FIG. 14 shows the corresponding total cell polarization. As expected, higher voltages were obtained at higher temperatures. In contrast to pressed-powder cells, the cell performance exhibited only a moderate temperature dependence. FIG. 15 shows cell voltage and total cell polarization for a pressed-powder cell with the same electrochemistry built and tested at Sandia National Laboratories. Notably, the performance degrades rapidly at 400° C. This temperature dependence was not observed for the cells having painted cathodes.

FIG. 16 shows discharge rates for cells having a pressed-powder cathode, a plasma sprayed cathode, and a painted cathode at 500° C. Pressed-powder anodes and separators were used for all tests. The plasma-sprayed cathode as treated exhibited a voltage transient spike at the beginning of discharge, indicating no or incomplete lithiation. The mass of active material for the painted cathode was about 0.10 g, compared to about 0.08 g for cathodes used in other tests. The pressed-powder separator was based on a LiCl—KCl eutectic and a Li(Si) anode. The plasma-sprayed cathode was prepared using elemental sulfur as a co-spray additive, and the excess sulfur was removed by leaching with CS₂ prior to cell assembly. The weights of the pressed-powder, plasma spray, and painted FeS₂ cathodes were 0.37 g, 0.093 g, and 0.10 g, respectively.

Notably, the painted cathode exhibits reduced cell polarization when compared to typical plasma-sprayed and pressed powder cells. For example, at a capacity of 1.5 eq. Li/mol the painted cathode cell has a cell polarization of about 0.27Ω, compared to polarizations of 0.3Ω or more for the plasma-sprayed and pressed powder cells; at a capacity of 3.25 eq. Li/mol, the painted cathode cell has a polarization of less than 0.2Ω, compared to 0.23Ω or more for the plasma-sprayed and pressed powder cells. The relative overall polarization may even have been higher for the sprayed electrodes than would be expected, due to a smaller diameter (1 inch, compared to 1.25 inches for the pressed-powder cell). Thus polarizations lower than those observed should be possible for a cell with a painted cathode when compared to a conventional cell of the same size. Since cell polarization is typically dominated by the cathode contribution, it is believed that this decreased polarization indicates that the painted cathode has better particle-to-particle contact than the plasma-sprayed and pressed powder cells.

The cells prepared by spraying or pasting exhibited a higher capacity, and the average polarization was lower later in the discharge, than the pressed-powder cell. The anode of the pressed-powder cell also used 25% electrolyte, compared to 15% for the painted anode.

While the present invention is described with respect to particular examples and preferred embodiments, it is understood that the present invention is not limited to these examples and embodiments. For example, many of the materials and structures described herein may be substituted with other materials and structures without deviating from the spirit of the invention. It is understood that various theories as to why the invention works are not intended to be limiting. The present invention as claimed therefore includes variations from the particular examples and preferred embodiments described herein, as will be apparent to one of skill in the art.

What is claimed is:

1. A method of fabricating a thermal battery electrode, comprising:
mixing a thermal electrode material, a thermal electrolyte material, a thickening agent, and water to form an aqueous slurry;
depositing the aqueous slurry onto a substrate;
vacuum-drying the substrate; and
cutting a thermal electrode from the substrate.

2. The method of claim 1, wherein the aqueous slurry is saturated with the thermal electrolyte material.

3. The method of claim 1, wherein the mixing and depositing steps are performed in a wet lab.

4. The method of claim 1, wherein depositing the aqueous slurry onto the substrate comprises spraying the slurry onto the substrate.

5. The method of claim 1, wherein depositing the aqueous slurry onto the substrate comprises pasting the slurry onto the substrate.

6. The method of claim 1, further comprising calendering the substrate prior to cutting the electrode from the substrate.

7. The method of claim 1, wherein the thermal electrode material is a cathode material.

8. The method of claim 1, wherein the thermal electrode material is a separator material.

9. A method of fabricating a thermal battery cell, comprising:
mixing a thermal cathode material, a thermal electrolyte material, a thickening agent, and water to form a cathode slurry;
depositing the cathode slurry onto a substrate;
vacuum drying the cathode slurry to form a cathode;
depositing a separator layer on the cathode;
depositing an anode on the separator; and
cutting a cell from the substrate.

10. The method of claim 9 wherein depositing the separator layer comprises:
mixing a separator material, the thermal electrolyte material, and water to form a separator slurry;
spraying the separator slurry onto the cathode; and
drying the separator slurry.

11. The method of claim 9, wherein the method is performed in a wet lab.

12. The method of claim 9, wherein the cathode slurry is saturated with the thermal electrolyte material.

13. The method of claim 9, wherein depositing the cathode slurry onto the substrate comprises spraying the slurry onto the substrate.

14. The method of claim 9, wherein depositing the cathode slurry onto the substrate comprises pasting the slurry onto the substrate.

15. The method of claim 9, wherein depositing the anode on the separator comprises:
mixing a thermal anode material and an organic binder to form an anode slurry;
depositing the anode slurry onto a current collector;
drying the anode slurry to form an anode; and
stacking the anode on the separator.

16. A method of fabricating a thermal battery cell, comprising:
spraying an aqueous cathode slurry on a first substrate to form a cathode;
spraying an aqueous separator slurry on the cathode to form a separator;
spraying an anode slurry on a second substrate to form an anode;
depositing a heat source on the second substrate, wherein the second substrate is disposed between the anode and the heat source; and
stacking the anode on the separator.

17. A thermal battery, comprising:
a heat source;
a collector;
a cathode fabricated by a process comprising spraying an aqueous slurry onto a substrate;
a separator; and
an anode;
wherein the battery has a lower polarization than a thermal battery having the same configuration and a cathode fabricated by a pressed-powder process.

18. The thermal battery of claim 17, wherein the cathode is fabricated by a process comprising:
mixing a thermal cathode material, a thermal electrolyte material, a thickening agent, and water to form a cathode slurry;
depositing the cathode slurry onto a substrate; and
vacuum drying the cathode slurry to form the cathode.

19. The thermal battery of claim 17, wherein the cathode has higher particle-to-particle contact than a cathode having the same dimensions fabricated by a pressed-powder process.
